(19) United States
(12) Patent Application Publication
(10) Pub. No.: US 2002/0039824 A1
(43) Pub. Date: Apr. 4, 2002

(54) Semiconductor device and a production method for the same

(75) Inventor: Naoki Tsuji, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/745,468

(22) Filed: Dec. 26, 2000

(30) Foreign Application Priority Data
Jul. 24, 2000 (JP) 2000-221942(P)

(51) Int. Cl. H01L 31/0336

(52) U.S. Cl. 438/268

(57) ABSTRACT

Trench isolation regions are formed on the main surface of a semiconductor substrate. A silicon nitride film and a silicon oxide film are formed so as to cover the trench isolation regions, which are patterned to expose the memory cell region. A gate oxide film is formed in the memory cell region under the condition of covering the peripheral circuit region with the silicon nitride film. The first gates are formed on this gate oxide film.

### BACKGROUND OF THE INVENTION

1. Field of the Invention

The present invention relates to a semiconductor device and a production method thereof, in particular, to a semiconductor device provided with trench isolations for electrically isolating elements and transistors with gate oxide films of which the thickness has at least two types or more and to the production method thereof.

2. Description of the Background Art

In the case that a trench isolation is used instead of a conventional LOCOS (Local Oxidation Of Silicon) for the isolation between elements, a trench is formed in the semiconductor substrate and the inside of this trench is filled with an oxide film by means of, for example, a CVD (Chemical Vapor Deposition) method or the like. Afterwards, elements such as MOS (Metal Oxide Semiconductor) transistors are formed on the main surface of the silicon substrate.

In a production process of semiconductor devices, an oxidation process after forming the trench isolations is inevitable. For example, when MOS transistors are formed on the main surface of a silicon substrate, a gate oxide film is formed through thermal oxidation of the main surface of the semiconductor substrate after forming the trench isolations.

At this time, an oxidizer disperses in the silicon oxide film which has been filled within the trenches so as to react with the silicon of the trench inner walls and the trench inner walls are oxidized. Thereby, the silicon of the trench inner walls is converted to a silicon oxide film. In the case that a silicon is converted to a silicon oxide film as described above, the volume of the silicon oxide film becomes approximately twice as large as the volume of the silicon which is oxidized.

The resultant condition becomes equal to the expansion of the silicon oxide film which is filled in within the trenches, and the active areas around the trenches undergo a compressive stress so that crystal defects are generated in the silicon substrate. A problem arises due to these defects generated in the substrate in that a junction leak current is increased so that the power consumption of the semiconductor device increases.

The above described problem easily arises in the case that a plurality of oxidation treatments are applied to the trench isolation regions, that is to say, it easily arises in a semiconductor device provided with transistors having gate oxide films of which the thickness has two types or more and, especially, the above described problem is significant in a non-volatile semiconductor memory device to which the oxidation process is applied heavily. Accordingly, it is desirable to reduce the oxidation amount which the trench isolations undergo.

### SUMMARY OF THE INVENTION

The present invention is provided to solve the above described problem. It is the purpose of the present invention that the generation of the defects due to an excessive oxidation of the trench isolation regions is limited in a semiconductor device which has trench isolations.

A semiconductor device according to the present invention provides with the first region where the first transistors having the first gate oxide films of the first thickness are formed, the second region where the second transistors having the second gate oxide films of the second thickness are formed, trench isolation regions which are selectively formed within the first and the second regions, a dummy region located between the first and the second regions having a plurality of dummy trench isolation regions and a positioning mark which is formed between the plurality of dummy trench isolation regions and which is used for positioning the mask film.

By providing such a positioning mark, a positioning of a mask film, such as a resist, can be carried out in a later process so as to be able to improve the dimension of the mask film and the positioning control. Thereby, for example, in the case that an anti-oxidation film is formed as described later, the edge of the anti-oxidation film can be located in a desired position without fail and it becomes possible to cover the trench isolation region within the second region with an anti-oxidation film at the time of forming the first gate oxide film without fail. Thereby, it becomes possible to limit the oxidation of the trench isolation region.

The above described semiconductor device preferably provides with a memory cell region where memory cell transistors are formed and a peripheral circuit region where a peripheral circuit which carries out an operation control of said memory cell transistors is formed. In this case, the above described first region includes a memory cell region and the second region includes a peripheral circuit region. More preferably, the semiconductor device is a non-volatile semiconductor memory device.

The present invention is particularly effective to a semiconductor device provided with a memory cell region and a peripheral circuit region as described above.

The positioning mark includes a trench part which is formed to connect the dummy trench isolation regions.

Thereby, the positioning mark can be formed in the same process as for the dummy trench isolation regions so that an increase of the production cost can be avoided.

A production or manufacturing method of the semiconductor device according to the present invention provides with the following steps. A trench isolation region is selectively formed within the first and the second regions of the semiconductor substrate. An anti-oxidation film is formed so as to cover the trench isolation region. The anti-oxidation film positioned over the first region is removed while leaving the anti-oxidation film over the second region. Under the condition where the second region is covered with the anti-oxidation film, the first gate of the first transistor is formed via the first gate oxide film over the first region. The anti-oxidation film positioned over the second region is removed. The second gate of the second transistor is formed via the second gate oxide film over the second region. Here, the anti-oxidation film is a film having an anti-oxidation, and typically a silicon nitride film, an oxynitride film or the like can be cited. An anti-oxidation film according to the present invention may be a film which includes a film having at least partially an anti-oxidation therein.

By forming the fist gate via the first gate oxide film over the first region under the condition where the second region is covered with the anti-oxidation film as described above, it is possible to prevent the trench isolation region within the second region from being oxidized at the time of forming the first gate oxide film.

The step of forming an anti-oxidation film preferably includes the step of forming an oxide film on the semiconductor substrate and the step of forming an anti-oxidation film over the oxide film. In this case, after removing the anti-oxidation film positioned over the first region, the oxide film is removed by carrying out wet etching using this anti-oxidation film as a mask.

In conventional process, the etching of the oxide film is carried out by using HF (Hydrogen Fluoride) with a resist as a mask. In this case, however, HF infiltrates under the resist so that the resist collapses, a region which is not supposed to be etched is etched or a stain is generated at the time of drying. Therefore, by etching the oxide film using the anti-oxidation film such as a silicon nitride film or an oxynitride film as a mask, HF can be prevented from infiltrating so as to solve the above described problem due to the infiltration of HF. In addition, an organic solvent such as isopropyl alcohol (IPA) can be utilized for drying so as to be able to limit the generation of stains.

In the case that an anti-oxidation film is formed over the oxide film, the thickness of the anti-oxidation film is preferably made smaller than the thickness of the oxide film.

Thereby, the etching can be stopped stably with the oxide film when the anti-oxidation film is removed through etching so that the substrate can be prevented from being etched.

The step of removing the anti-oxidation film located over the first region preferably includes the step of forming a mask film, which has openings above the first region, over the anti-oxidation film and the step of selectively removing the anti-oxidation film using the mask film. In this case, the mask film is used to carry out a channel doping for controlling the threshold voltage of the first transistors in the first region of the semiconductor substrate.

Thereby, the mask film for removing the anti-oxidation film can also be used as a mask film for the channel doping for controlling the threshold value of the transistors formed in the first region so that an increase of a lithography process can be limited.

A border region having a dummy gate is provided preferably between the first and the second regions. In this case, the step of removing the anti-oxidation film positioned over the first region includes the step of forming a first mask film which reaches the border region over the anti-oxidation film and the step of selectively removing the anti-oxidation film using the first mask film. In addition, the step of removing the anti-oxidation film positioned over the second region includes the step of forming a second mask film over the first gate so as to be overlapped with the anti-oxidation film and the step of selectively removing the anti-oxidation film using the second mask film. Moreover, the step of forming the second gate includes the step of forming a dummy gate so as to cover the anti-oxidation film.

By selectively removing the anti-oxidation film using the second mask film which is formed so as to be overlapped with the anti-oxidation film as described above, the oxidation of the trench isolation region positioned in or in the vicinity of the border region can be prevented from being oxidized without fail at the time of forming the first gate oxide film.

Semiconductor devices, to which a production method according to the present invention can be applied, preferably provides with a memory cell region where memory cell transistors are formed and a peripheral circuit region where a peripheral circuit which carries out the operation control of said memory cell transistors is formed. In this case the above described first region includes a memory cell region and the second region includes a peripheral circuit region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 14 are cross section views showing the first to fourteenth steps of a production method of a semiconductor device according to the present invention;

FIG. 15 is a section view showing a semiconductor device according to the present invention;

FIG. 16 is a plan view showing isolation regions of a semiconductor device of a conventional example;

FIG. 17 is a plan view showing a positioning mark of a semiconductor device according to the present invention;

FIG. 18 is a plan view showing a mask pattern for forming lower layer gates in the L direction in a semiconductor device according to the present invention; and

FIG. 19 is a plan view showing the upper layer gates, dummy gates and selection gates in a semiconductor device according to the present invention.

### DESCRIPTION OF THE PREFERED EMBODIMENTS

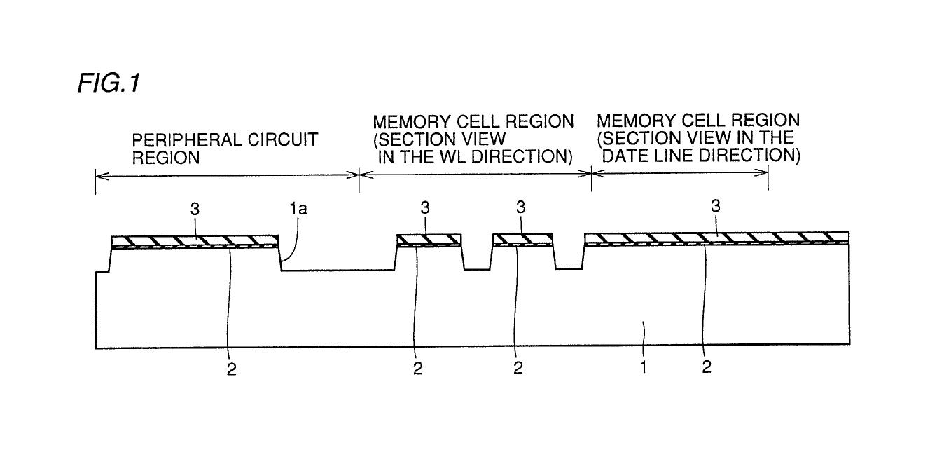

In the following, embodiments of the present invention are described in reference to FIGS. 1 to 19.

### First Embodiment

FIGS. 1 to 14 are cross section views showing the first to the fourteenth steps of a production method of a semiconductor device according to the first embodiment. FIG. 15 is a cross section view showing a semiconductor device in the first embodiment.

An AND-type non-volatile semiconductor memory device which has trench isolations as element isolations and two or more gate oxide films of different the thickness is cited as an example. In a semiconductor device other than the AND-type non-volatile semiconductor memory device, however, it is possible to apply the present invention to a semiconductor device having trench isolations and gate oxide films of which the thickness has two types or more.

As shown in FIG. 1, a silicon oxide film 2 is formed through thermal oxidation and a silicon nitride film 3 is formed by a CVD method or the like on the main surface of a silicon substrate 1. The thickness of the silicon oxide film 2 is 18 nm and the thickness of the silicon nitride film 3 is 140 nm. Next, a trench 1a is formed in the silicon substrate 1 by dry etching or the like with a photoresist as a mask.

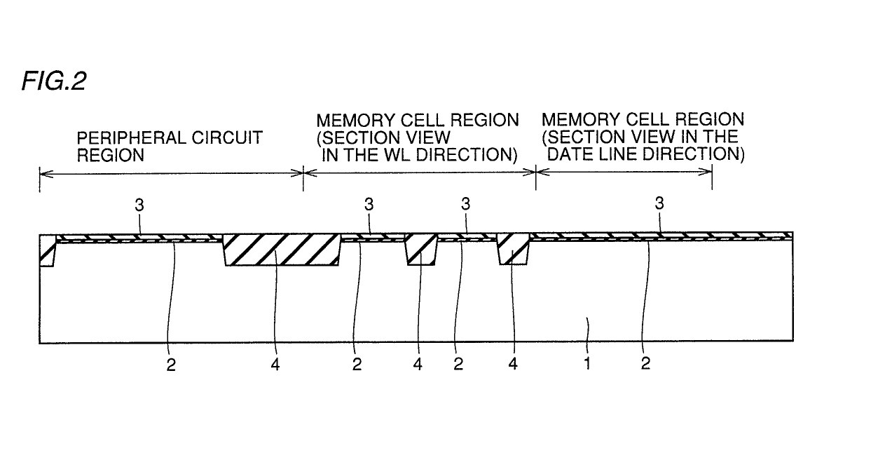

After oxidation of the inner walls of the trench 1a to approximately 50 nm, a silicon oxide film is deposited on the silicon substrate 1 so as to cover the trench 1a using a CVD method or the like. A CMP (Chemical Mechanical Polishing) process is applied to this silicon oxide film so that a silicon oxide film 4 is filled within the trench 1a as shown in FIG. 2.

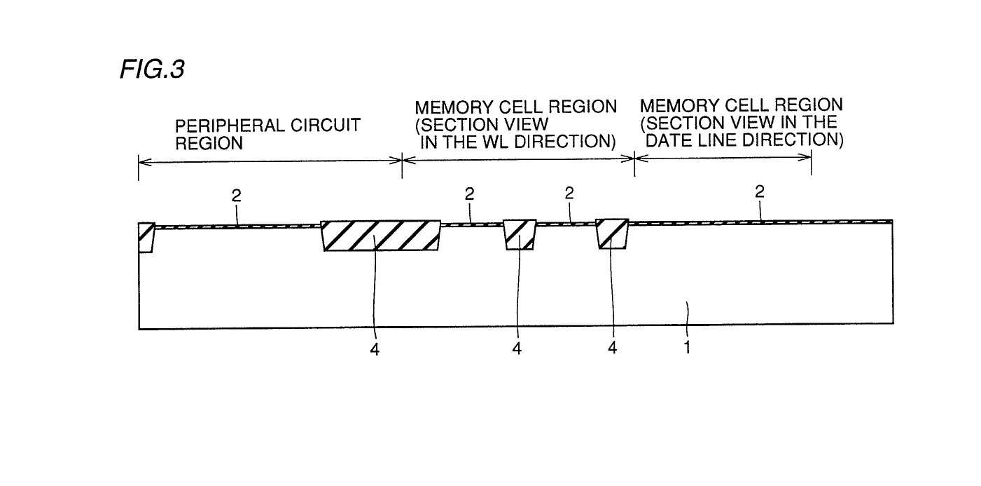

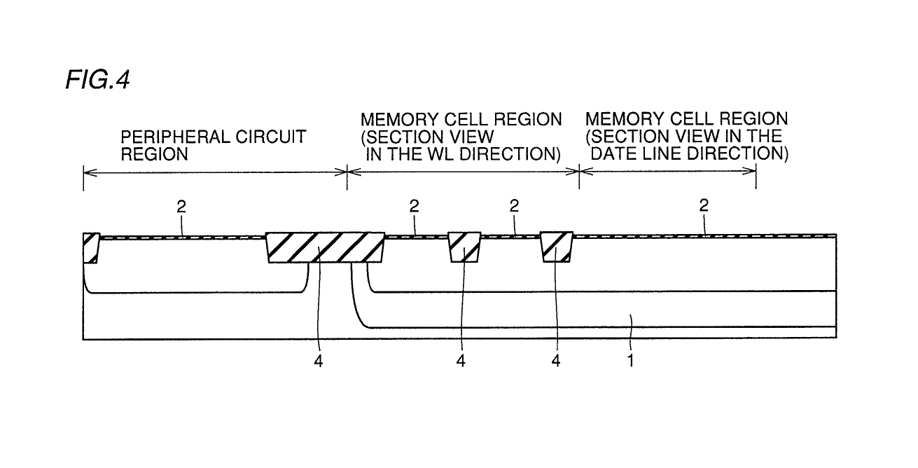

Afterwards, etching of the silicon oxide film by fluoride acid and etching of the silicon nitride film 3 by thermal phosphate are carried out so that element isolations (trench isolations) are formed as shown in FIG. 3. At this time the approximately 15 nm of silicon oxide film 2 remains on the active area of the silicon substrate 1. An impurity implantation for forming a p-well and an n-well with this oxide film as a temporary oxide film and a channel doping for a peripheral circuit region are carried out using masks, respectively, so that a desirable impurity profile is formed within the silicon substrate 1 as shown in FIG. 4.

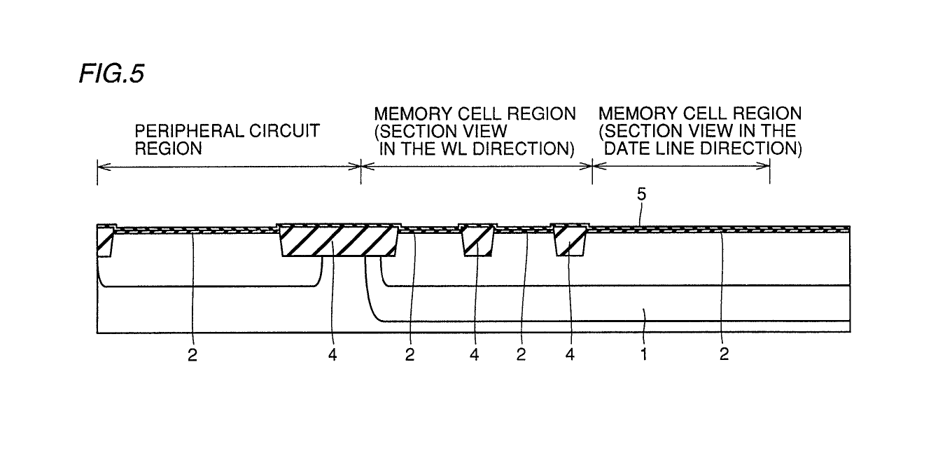

Next, as shown in FIG. 5 a silicon nitride film 5 of approximately 5 to 15 nm is deposited using a CVD method or the like. This silicon nitride film 5 functions as an oxidation preventive film which prevents the peripheral circuit region from being oxidized at the time of forming a tunnel oxide film. Accordingly, it is preferable for the silicon nitride film 5 to have a thickness large enough to prevent the oxidation and to have a thickness equal to or less than that of the silicon oxide film 2 which is a temporary oxide film in order to prevent the etching from reaching the silicon substrate 1 at the time of removal of the silicon nitride film 5 of the memory cell region.

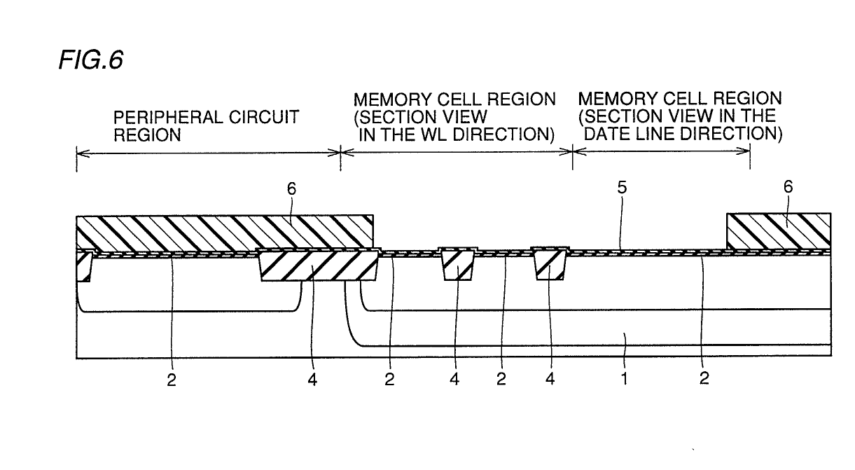

Next, as shown in FIG. 6, a resist pattern 6 which has an opening above the memory cell region is formed. This resist pattern 6 serves as a mask for channel doping to control the threshold voltage of the memory cell transistors and, at the same time, serves as a mask when the silicon nitride film 5 is removed in the memory cell region. Accordingly, even in the case that the process of the present invention, which covers only the peripheral circuit part with the silicon nitride film 5, no steps of the lithography process are increased in number compared to a conventional process.

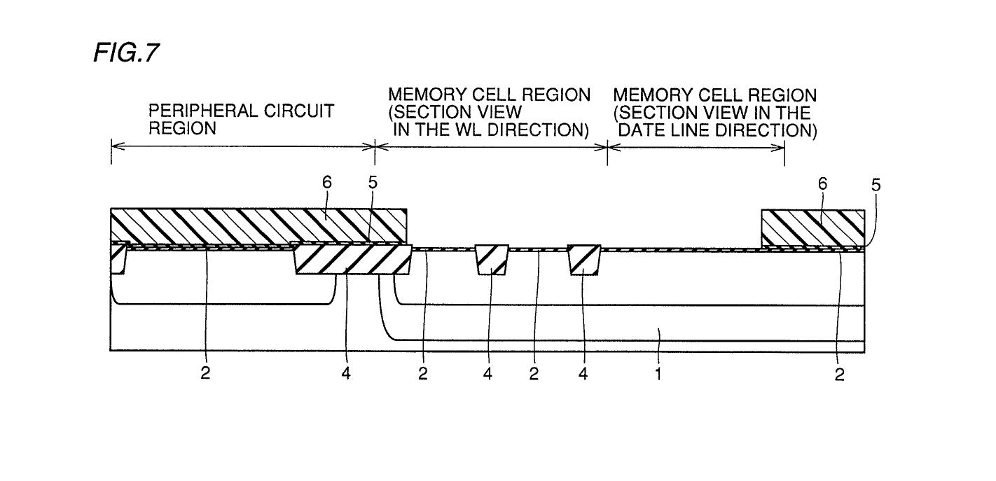

Next, as shown in FIG. 7, the silicon nitride film 5 above the memory cell region is removed by carrying out dry etching with the resist pattern 6 as a mask. At this time the silicon oxide film 2 is also etched at the time of over-etching.

The etching can be stopped at silicon oxide film 2 by carrying out dry etching under the condition where the etching of the silicon nitride film 5 progresses faster than that of the silicon oxide film 2. The etching can be stopped at silicon oxide film 2 without fail by making the thickness of the silicon nitride film 5 smaller than the thickness of the silicon oxide film 2. Here, after the above described etching the silicon oxide film 2 of the thickness of approximately 10 nm can remain on the silicon substrate 1.

Next, an impurity implantation (channel doping) of boron or the like is carried out with the resist pattern 6 as a mask in order to make the threshold voltage of the memory cell transistors a desirable value. Here, this impurity implantation may be carried out before the dry etching of the silicon nitride film 5.

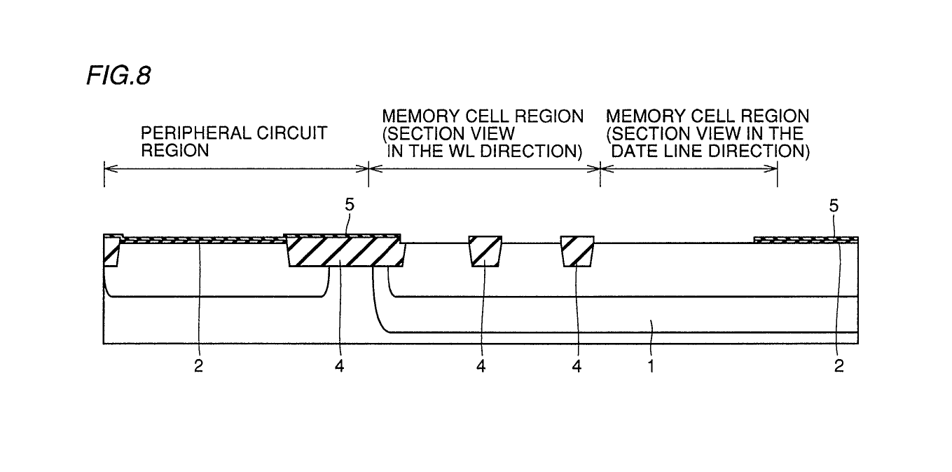

After removing the resist pattern 6 with H₂SO₄/H₂O₂ liquid or the like, the silicon oxide film 2 above the memory cell region is removed by carrying out an HF treatment with the silicon nitride film 5 as a mask as shown in FIG. 8. Thereby, the main surface of the silicon substrate 1 in the memory cell region is exposed.

A conventional process also has a process of removing the silicon oxide film 2 of the memory cell region first and of removing the silicon oxide film 2 of the peripheral circuit region later. In the conventional process, however, the HF treatment should be carried out with the photoresist as a mask.

In this case, since the contact between the photoresist and the silicon oxide film 2 is not close enough, there is a problem that HF infiltrates under the resist which, essentially, is not supposed to be etched. There is also the problem that stains easily occur on the wafer surface since an organic solvent such as isopropyl alcohol cannot be used for drying because of the existence of the resist in the surface drying step after the etching by HF.

According to the present invention, however, since the silicon oxide film 2 is etched using the silicon nitride film 5 which is not etched by HF as a mask, no problem arises in that infiltration of HF occurs, such as in the case of the conventional process, and no stains occur at the time of drying.

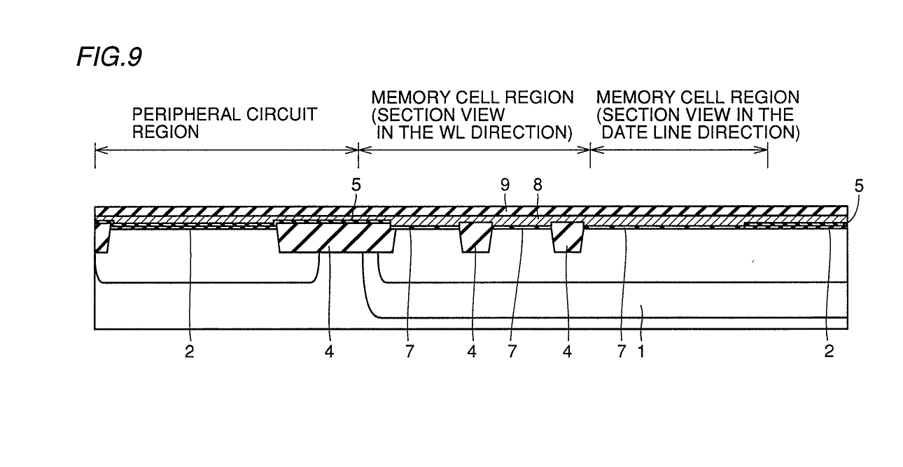

Next, as shown in FIG. 9, a gate oxide film, (tunnel oxide film) 7 of approximately 9 nm is formed through thermal oxidation as shown in FIG. 9 on which a doped amorphous silicon 8 of approximately 100 nm which becomes a lower layer gate (first gate) and a silicon nitride film 9 of approximately 200 nm are deposited.

At this time though the main surface of the silicon substrate 1 in the memory cell region, which is exposed, is oxidized by approximately 9 nm, the trench isolations in the peripheral circuit region is not oxidized since the silicon nitride film 5 works as an oxidation preventive film due to the fact that the peripheral circuit region is covered with the silicon nitride film 5. That is to say, the trench isolations in the peripheral circuit region do not undergo an oxidation stress at the time of tunnel oxidation. Accordingly, the silicon oxide film 4 within the trench isolation region in the peripheral circuit region won't expand through oxidation.

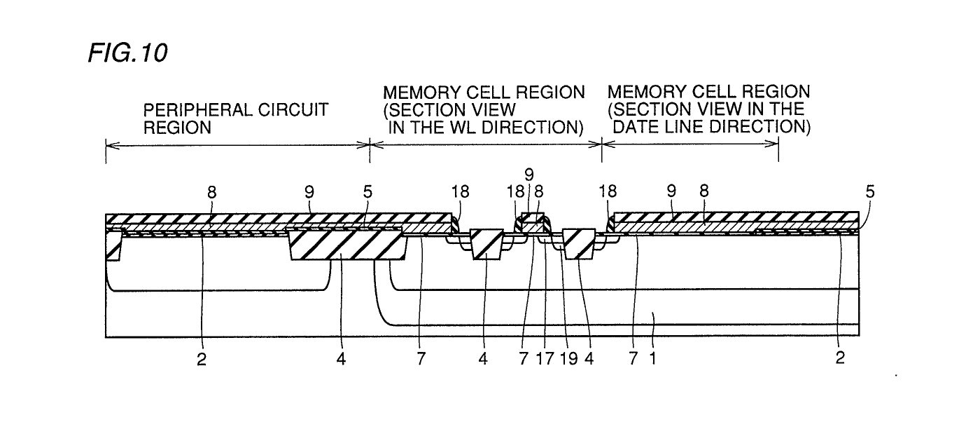

Next, a resist pattern is formed on the silicon nitride film 9 and this is used as a mask to etch the silicon nitride film 9. Afterwards, the resist pattern is removed. Then, as shown in FIG. 10, the doped amorphous silicon 8 is etched using the patterned silicon nitride film 9 as a mask. Thereby, the lower layer gates of the AND-type non-volatile semiconductor memory device are formed in the L direction (word line direction or WL direction).

Next, As (arsenic) is implanted by approximately 2×10¹⁴ with 40 keV in order to form an n⁻ diffusion layer 17 of the memory cell transistors. After depositing a TEOS (Tetra Etyle Ortho Silicate) oxide film of 50 nm an isotropic etching is applied to form a side wall isolation film 18. This side wall isolation film 18 is used as a mask to implant As by approximately 1×10¹⁵ with 40 keV. Thereby, an LDD (Lightly Doped Drain) structure is formed.

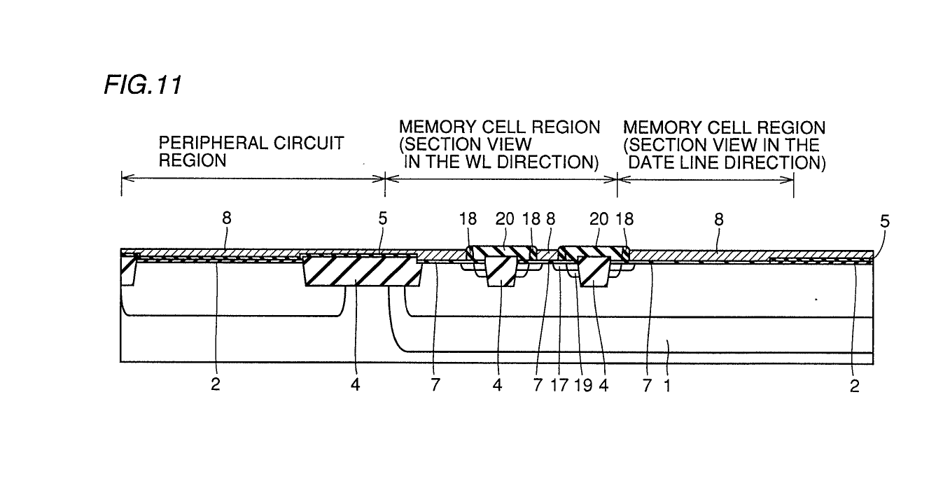

Next, a silicon oxide film is deposited of approximately 600 nm by a CVD method, to which a CMP process is applied and dry etching of the oxide film is carried out so that the silicon nitride film 9 on the lower layer gates is removed by thermal phosphate. Thereby, as shown in FIG. 11, a silicon oxide film 20 is formed.

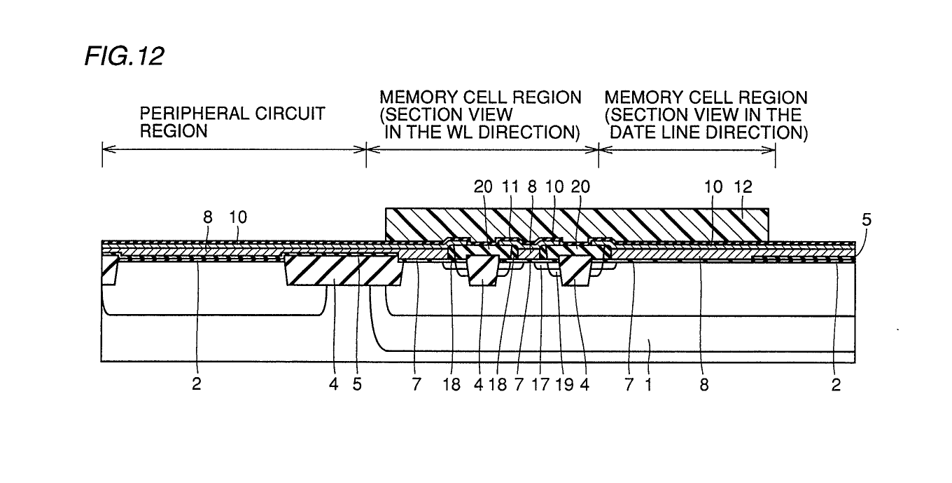

A doped amorphous silicon 10 of approximately 40 nm is deposited so as to cover the silicon oxide film 20 and this doped amorphous silicon 10 is etched with the resist as a mask. Thereby, as shown in FIG. 12, fins are added to the lower gates.

Next, an oxide film, a nitride film and an oxide film are deposited by 6 nm, 9 nm and 6 nm, respectively, by a CVD method. The isolation film of this three layer structure becomes an ONO film 11 of the AND-type non-volatile semiconductor memory device.

As shown in FIG. 12, a resist pattern 12 which has an opening above the peripheral circuit region is formed on the ONO film 11. This resist pattern 12 is used as a mask to carry out dry etching and the ONO film 11 and the doped amorphous silicon 10 above the peripheral circuit region are removed. At this time a silicon nitride film 5 and a silicon oxide film 2 remain on the active region in the peripheral circuit region in the case of the present invention.

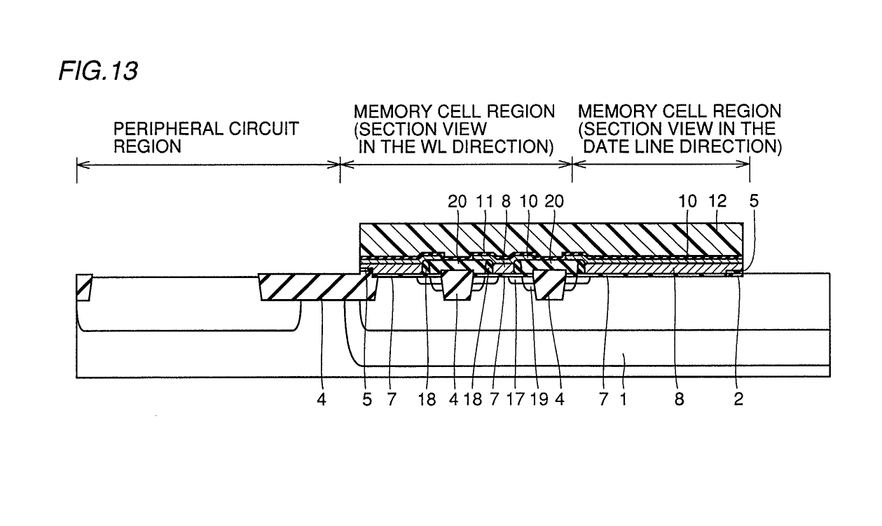

Next, the silicon nitride film 5 above the peripheral circuit region is removed by carrying out dry etching with the resist pattern 12 as a mask (see FIG. 13). At this time, since the dry etching is carried out under the condition where the etching rate is faster in the silicon nitride film than in the silicon oxide film, the silicon oxide film 2 with reduced film thickness remains in the peripheral circuit region after the dry etching. Afterwards, as shown in FIG. 13, the silicon oxide film 2 on the active region in the peripheral circuit region is removed by an HF treatment.

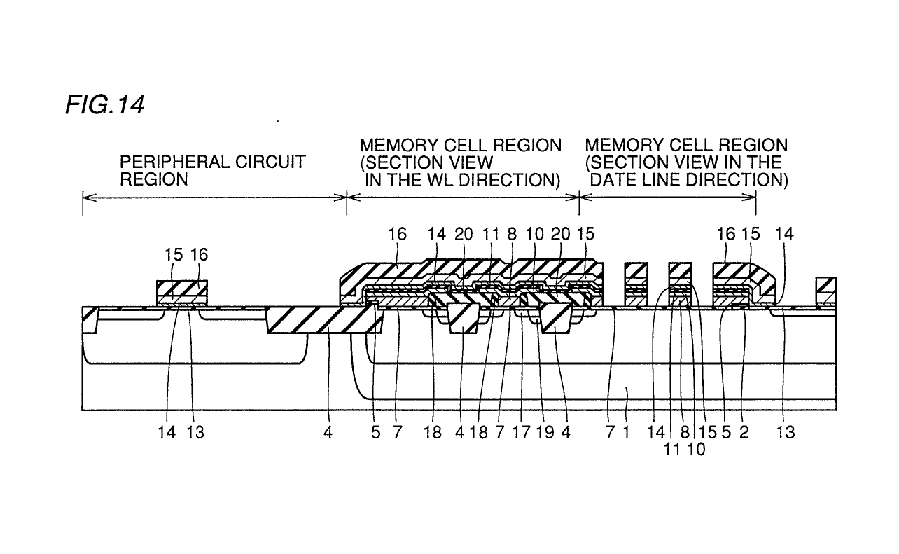

Next, after the resist pattern 12 is removed with H₂SO₄/H₂O₂ liquid, a gate oxide film 13 for the transistors of the peripheral circuit is formed by thermal oxidation as shown in FIG. 14. Since the memory cell region is covered with the ONO film 11 at this time it is not oxidized. Afterwards, the doped amorphous silicon film 14, a WSi film 15 and a silicon oxide film 16 are deposited in sequence.

Next, a resist pattern is formed for patterning the gates (second gates) of the transistors of the peripheral circuit region and for patterning upper layer gates of the memory cell transistors in the W direction (data line direction or bit line direction) and the silicon oxide film 16 is etched with this resist pattern as a mask.

Afterwards, the resist pattern is removed and the doped amorphous silicon film 14 and the WSi film 15 are etched with the silicon oxide film 16 as a mask. Thereby, the gates of the transistors in the peripheral circuit region and the upper layer gates of the memory cell transistors are formed.

Next, a resist pattern having an opening above the memory cell region is formed and dry etching is carried out with this resist pattern as a mask. Thereby, a patterning for the lower gates of the memory cell transistors is carried out in the W direction. Afterwards, the resist pattern is removed.

Next, the source/drain implantation for the p-channel transistors and the n-channel transistors is carried out in the peripheral circuit region so as to form transistors of the peripheral circuit region as shown in FIG. 14.

Afterwards, inter-layer isolation films 21 to 26, Al wires 27 and 28 for electrically connecting respective transistors and the like are formed so as to form an AND-type non-volatile semiconductor memory device as shown in FIG. 15.

### Second Embodiment

Next, the second embodiment of the present invention is described. In the second embodiment, an oxynitride (SiON) film is used instead of the silicon nitride film 5.

In this case, the oxynitride film 5 which covers the peripheral circuit region serves as an oxidation preventive film in the same way as the case of the silicon nitride film 5 so that the trench isolations in the peripheral circuit region are not oxidized at the time of forming the gate oxide film of the memory transistors. Accordingly, the silicon oxide film filled in within the trench isolation regions of the peripheral circuit region won't expand through the above described oxidation.

Here, any isolation film other than oxynitride film, as long as it has anti-oxidation properties, can be adopted. In addition, an isolation film which includes a film having anti-oxidation characteristics can be utilized as an anti-oxidation film according to the present invention.

### Third Embodiment

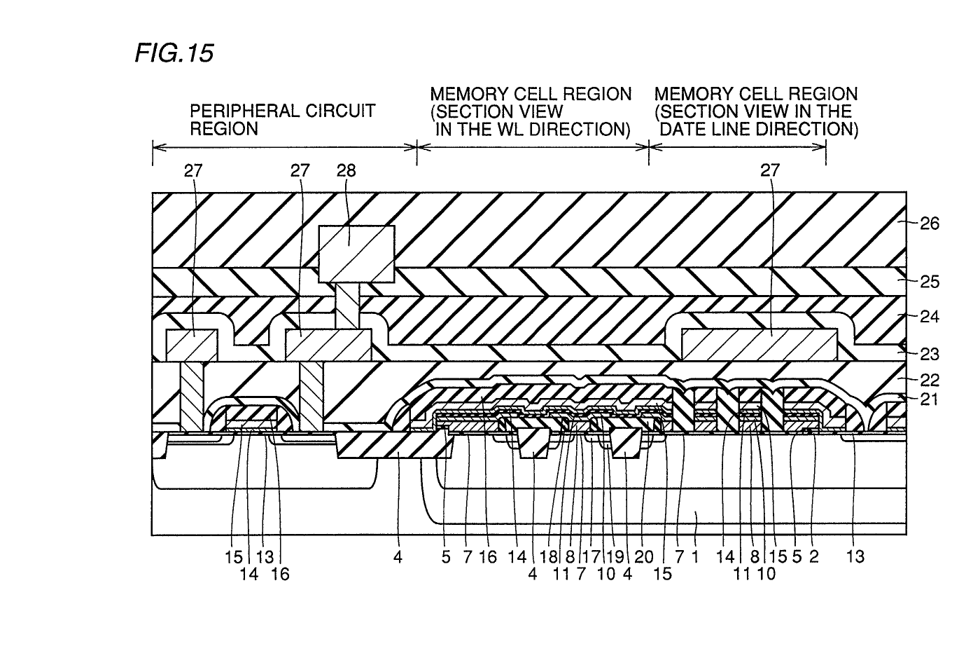

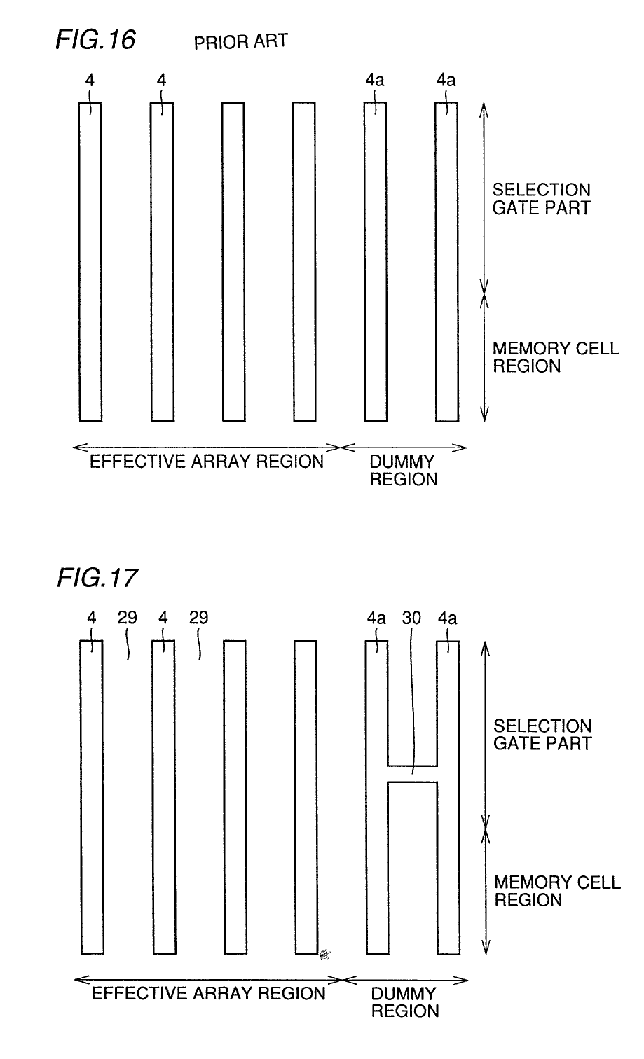

Next, the third embodiment of the present invention is described in reference to FIGS. 16 to 19. FIGS. 16 to 19 show plan views of the memory cell block in an AND-type non-volatile semiconductor memory device according to the present invention.

As shown in FIG. 16, the element isolation pattern is a simple line and space pattern within the memory cell block of the AND-type non-volatile semiconductor memory device. Here, a peripheral circuit region exists partially within the memory cell block.

As shown in FIG. 16 since there is no standard or a mark in the longitudinal direction (the longer direction of each trench isolation region), the border between the memory cell region and the peripheral circuit region within the memory cell block cannot be distinguished until the ONO film 11 is patterned in the lateral direction of the FIG. 16 at the stage as shown in FIG. 12, for example.

Accordingly, the positioning of the resist pattern 6 at the stage of FIG. 6 is difficult and, therefore, the resist pattern 6 cannot be formed with precision.

Therefore, a mark 30 for positioning the mask film is formed between the trench isolation regions 4a in a dummy region as shown in FIG. 17 according to the present invention. That is to say, the positioning mark 30 is formed in the border region between the memory cell region and the peripheral circuit region.

Here, the above described dummy regions (border regions) are provided adjacent to the effective array regions, which are located on both ends of the memory cell block. Within these dummy regions two, or more, trench isolation regions 4a exist.

In the embodiment as shown in FIG. 17 a position mark 30 is created by forming a trench connecting the adjacent trench isolation regions 4a and by filling in a silicon oxide film within this trench. However, any other pattern which can be utilized as a mark for positioning the mask film can be adopted.

For example, in the case of the existence of the positioning mark 30 between the trench isolation regions 4a, it is not necessary to connect the trench isolation regions 4a and the shape of the positioning mark 30 is arbitrarily selectable.

By providing the above described positioning mark 30, the positioning of the resist pattern 6 of FIG. 6 can be carried out with precision and the resist pattern 6 can be formed with precision. And, in the case that the trench isolation regions 4a in the dummy region are connected as shown in FIG. 17, no real circuits are negatively affected.

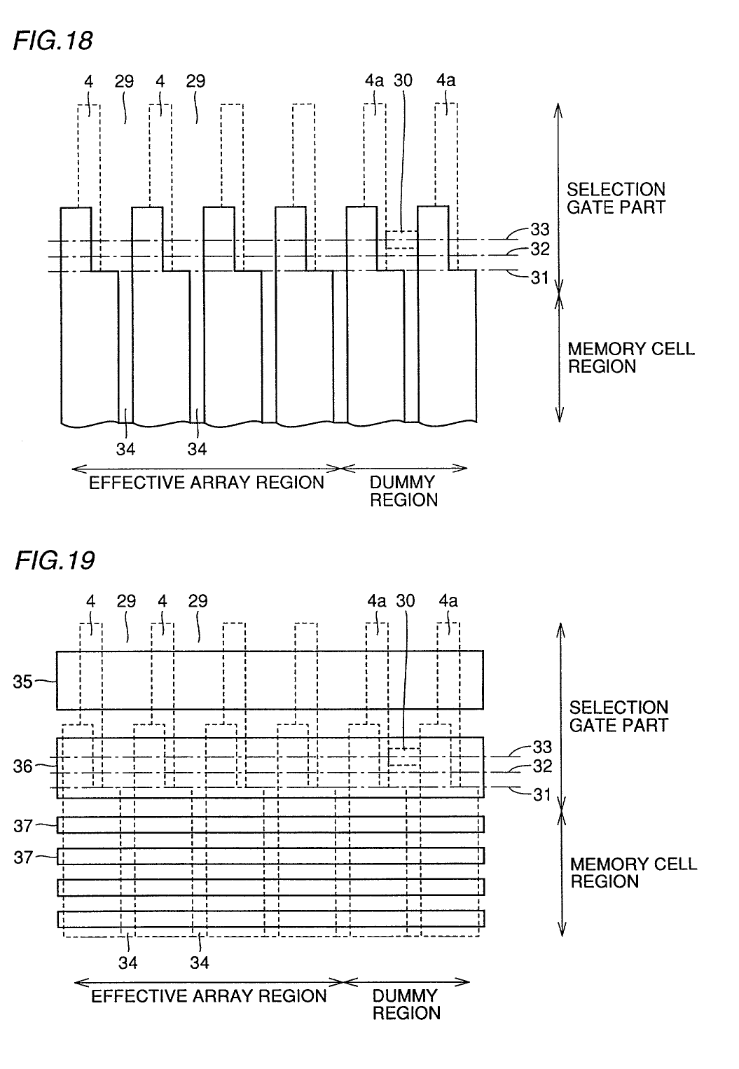

As shown in FIG. 18, the borderline 32 along the edge of the selection gate part side in the resist pattern 6 is located closer to the memory cell region side than the borderline 33 along the edge of the selection gate part side in the resist pattern 12. And the borderlines 32 and 33 are located closer to the peripheral circuit region side than the borderline 31 along the narrower part on one end of the pattern 34 for forming lower layer gates in the L direction. Here, in FIG. 18, the region surrounded by a solid line corresponds to an opening part of the resist pattern for forming the above described lower gates in the L direction. The opening part of the above described resist pattern 6 is located closer to the memory cell side than the borderline 32 and the opening part of the resist pattern 12 is located on the opposite side of the memory cells from the borderline 33.

Since one end of the resist pattern 12 is located closer to the peripheral circuit region side than one end of the resist pattern 6 as described above, the silicon nitride film 5 ultimately remains in the region between the borderlines 32 and 33.

In the case that the location relationship between the borderlines 32 and 33 is reversed the trench isolation region located in the region between the borderlines 32 and 33 undergoes double oxidation which is the tunnel oxidation of the memory cell transistors and the gate oxidation of the peripheral circuit region and, therefore, it becomes easy for crystal defects to occur in the vicinity of the above described trench isolation region.

However, by arranging the peripheral circuit region closer to the borderline 33 than to the borderline 32, the trench isolation region located within the region between the borderlines 32 and 33 can be prevented from being oxidized twice as described above. Thereby, the generation of crystal defects in the vicinity of the above described trench isolation region can be limited.

In addition, since an impurity implantation for determining the threshold voltage of the memory cell transistors must be carried out without fail in the region located closer to the memory cell region side than to the borderline 31, the borderline 32 must exist closer to the peripheral circuit region side than to the borderline 31.

As shown in FIG. 19 the selection gate 35 and the dummy gate 36 are also patterned at the time of patterning of the word lines (the upper layer gates) 37 of the memory cell transistors in the W direction. Thereby, the dummy gate 36 is formed in the border region so as to ultimately divide the memory cell region and the peripheral circuit region.

At this time both ends of the dummy gate 36 are patterned outside of the borderline 31 and 33 as shown in FIG. 19. Thereby, the silicon nitride film 5 ultimately exists only under the dummy gate 36. Accordingly, the transistors within the memory cell region and the peripheral circuit region are not negatively affected.

As described above, according to the present invention, the trench isolation regions within the second region can be prevented from being oxidized at the time of forming the first gate oxide film of the first transistors and, therefore, the trench isolation regions can be prevented from being excessively oxidized such as in a prior art. Thereby, crystal defects can be prevented from occurring in the substrate due to the above described excessive oxidation and, therefore, a semiconductor device with high reliability can be gained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a first region where first transistors each having a first gate oxide film of a first thickness is formed;
a second region where second transistors each having a second gate oxide film of a second thickness are formed;
trench isolation regions formed selectively within said first and second regions;
a dummy region having a plurality of dummy trench isolation regions located between said first and said second regions; and
a positioning mark which is formed between said plurality of dummy trench isolation regions and which is used for positioning a mask film.

2. A semiconductor device according to claim 1, wherein said semiconductor device comprises a memory cell region in which memory cell transistors are formed and a peripheral circuit region in which a peripheral circuit for controlling the operation of said memory cell transistors is formed and wherein said first region includes said memory cell region and said second region includes said peripheral circuit region.

3. A semiconductor device according to claim 2, wherein said semiconductor device includes a non-volatile semiconductor memory device.

4. A semiconductor device according to claim 1, wherein said positioning mark includes a trench part formed so as to connect said dummy trench isolation regions.

5. A production method for a semiconductor device comprising:
the step of selectively forming trench isolation regions within a first and a second region of a semiconductor substrate;
the step of forming an anti-oxidation film so as to cover said trench isolation regions;
the step of removing said anti-oxidation film located in said first region so that said anti-oxidation film remains in said second region;
the step of forming first gates of first transistors via first gate oxide film in said first region under a condition where said second region is covered with said anti-oxidation film;
the step of removing said anti-oxidation film located in said second region; and
the step of forming second gates of second transistors via second gate oxide film in said second region.

6. A production method of a semiconductor device according to claim 5, wherein the step of forming said anti-oxidation film includes the step of forming an oxide film on said semiconductor substrate and the step of forming said anti-oxidation film on said oxide film and further comprising the step of removing said oxide film by carrying out wet etching using said anti-oxidation film as a mask after removing said anti-oxidation film located in said first region.

7. A production method for a semiconductor device according to claim 5, wherein the step of forming said anti-oxidation film includes the step of forming an oxide film on said semiconductor substrate and the step of forming said anti-oxidation film on said oxide film so that the thickness of said anti-oxidation film becomes lesser than the thickness of said oxide film.

8. A production method for a semiconductor device according to claim 5, wherein the step of removing said anti-oxidation film located in said first region includes the step of forming a mask film having an opening above said first region on said anti-oxidation film and the step of selectively removing said anti-oxidation film using said mask film, and further comprising the step of carrying out a channel doping in the first region of said semiconductor substrate using said mask film.

9. A production method for a semiconductor device according to claim 5, wherein a border region having a dummy gate between said first and said second regions is provided;
the step of removing said anti-oxidation film located in said first region includes the step of forming a first mask film reaching said border region on said anti-oxidation film and the step of selectively removing said anti-oxidation film using said first mask film;
the step of removing said anti-oxidation film located in said second region includes the step of forming a second mask film on said first gates so as to be overlapped with said anti-oxidation film and the step of selectively removing said anti-oxidation film using said second mask film; and
the step of forming said second gates includes the step of forming said dummy gate so as to cover said anti-oxidation film.

10. A production method for a semiconductor device according to claim 5, wherein said semiconductor device comprises a memory cell region in which memory cell transistors are formed and a peripheral circuit region in which a peripheral circuit for controlling the operation of said memory cell transistors is formed and wherein said first region includes said memory cell region and said second region includes said peripheral circuit region.
